(19) United States
(12) Patent Application Publication
(10) Pub. No.: US 2024/0128172 A1
(43) Pub. Date: Apr. 18, 2024

(54) SEMICONDUCTOR PACKAGE

(71) Applicant: Samsung Electronics Co., Ltd., Suwon-si (KR)

(72) Inventors: Inwon O, Suwon-si (KR); Jaesun Kim, Suwon-si (KR); Yunseok Choi, Suwon-si (KR)

(21) Appl. No.: 18/235,596

(22) Filed: Aug. 18, 2023

(30) Foreign Application Priority Data
Oct. 18, 2022 (KR) 10-2022-0134211

(51) Int. Cl. H01L 23/498

(52) U.S. Cl. CPC H01L 23/49816; H01L 23/49822; H01L 23/49838; H01L 24/16; H01L 2224/16227

(57) ABSTRACT

A semiconductor package includes a package substrate including a ball pad with first and second pads, a wiring line extending between the first and second pads, and a solder mask layer including a first opening exposing a portion of the first pad and a second opening exposing a portion of the second pad, and a semiconductor chip on an upper surface of the package substrate, and a connection bump on a lower surface of the ball pad and connected to the first and second pads. The connection bump covers a lower surface and a first side surface of the first pad exposed through the first opening, a lower surface and side surfaces of a region of the solder mask layer covering the wiring line, and a lower surface and a first side surface of the second pad exposed through the second opening.

### CROSS-REFERENCE TO RELATED APPLICATION(S)

This application claims benefit of priority to Korean Patent Application No. 10-2022-0134211 filed on Oct. 18, 2022 in the Korean Intellectual Property Office, the disclosure of which is incorporated herein by reference in its entirety.

### BACKGROUND

The present inventive concept relates to a semiconductor package.

The semiconductor package is mounted on an external substrate, such as a main board, through connection bumps having various shapes. The connection bumps are connected to the ball pads of a package substrate and connected to the external substrate, and the ball pads are arranged in a generally regular shape on a lower surface of the package substrate. Accordingly, wiring patterns for routing are arranged in a space around the ball pads.

### SUMMARY

An aspect of the present inventive concept is to provide a semiconductor package having improved design ease and reliability.

According to an aspect of the present inventive concept, a semiconductor package includes a package substrate, a semiconductor chip, and a connection bump. The package substrate includes a ball pad including first and second pads on a lower surface of the package substrate, a wiring line extending between the first pad and the second pad on the lower surface, and a solder mask layer covering the wiring line and the ball pad. The solder mask layer includes a first opening exposing a portion of the first pad and a second opening exposing a portion of the second pad. The semiconductor chip is on an upper surface of the package substrate, and the connection bump is on a lower surface of the ball pad and connected to the first and second pads. The connection bump covers a lower surface and a first side surface of the first pad exposed through the first opening, a lower surface and side surfaces of a region of the solder mask layer covering the wiring line, and a lower surface and a first side surface of the second pad exposed through the second opening.

According to another aspect of the present inventive concept, a semiconductor package includes a package substrate and a connection bump. The package substrate includes a first ball pad including a first pad and a second pad that are disposed on a lower surface of the package substrate, a second ball pad including a third pad having a first shape and disposed on the lower surface of the package substrate, a wiring line extending between the first pad and the second pad on the lower surface, and a solder mask layer covering the wiring line and the first ball pad, wherein the solder mask layer includes a first opening exposing a portion of the first pad and a second opening exposing a portion of the second pad. The connection bump is on a lower surface of the first ball pad and connected to the first and second pads. The first pad has a shape corresponding to a first portion of the first shape of the third pad in a plan view. The second pad has a shape corresponding to a second portion of the first shape of the third pad in a plan view. The connection bump contacts a portion of a lower surface and a side surface of each of the first and second pads.

According to another aspect of the present inventive concept, a semiconductor package includes a package substrate including a first ball pad on a lower surface of the package substrate, a second ball pad on the lower surface of the package substrate, and a solder mask layer exposing portions of each of the first and second ball pads, a semiconductor chip on an upper surface of the package substrate, a first connection bump on a lower surface of the first ball pad and connected to the first ball pad, and a second connection bump on a lower surface of the second ball pad and connected to the second ball pad. The first ball pad includes first and second pads each having a shape corresponding to a portion of a first figure. The second ball pad includes third and fourth pads each having a shape corresponding to a portion of a second figure. The package substrate further includes a first wiring line extending between the first pad and the second pad on the lower surface of the package substrate, and a second wiring line between the third pad and the fourth pad on the lower surface of the package substrate. The first ball pad has a shape different from a shape of the second ball pad.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view of a semiconductor package according to example embodiments.

FIG. 2 is a partial enlarged view of a semiconductor package according to example embodiments.

FIG. 3 is a partial plan view of a semiconductor package according to example embodiments.

FIGS. 4A and 4B are partial enlarged views of a semiconductor package according to example embodiments.

FIGS. 5A to 5C are plan views of a semiconductor package according to example embodiments.

FIGS. 6A and 6B are partial enlarged views of a semiconductor package according to example embodiments.

FIG. 7 is a cross-sectional view of a semiconductor package according to example embodiments.

FIG. 8 is a partial enlarged view of a semiconductor package according to example embodiments.

FIGS. 9 and 10 are cross-sectional views of a semiconductor package according to example embodiments.

### DETAILED DESCRIPTION

Hereinafter, example embodiments of the present inventive concept will be described with reference to the accompanying drawings.

Unless otherwise specified, in this specification, terms such as “upper portion,” “upper surface,” “lower portion,” “lower surface,” “lateral surface,” and the like, are determined based on the drawings, and in actuality, the terms may be changed according to a direction in which a device or an element is disposed.

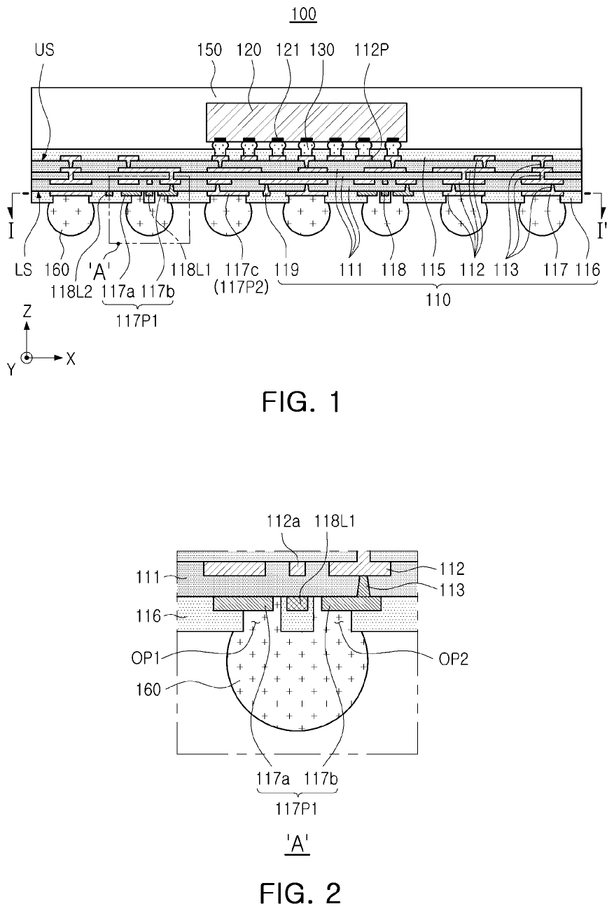

FIG. 1 is a cross-sectional view of a semiconductor package according to example embodiments.

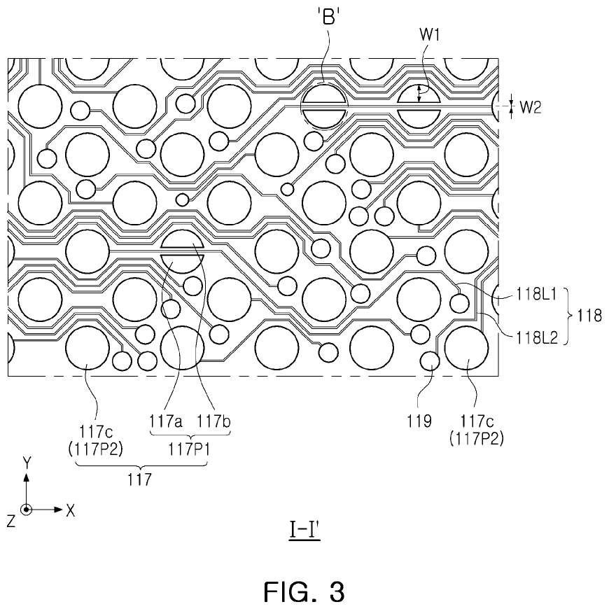

FIG. 2 is a partial enlarged view of a semiconductor package according to example embodiments. FIG. 2 is an enlarged view of region ‘A’ of FIG. 1.

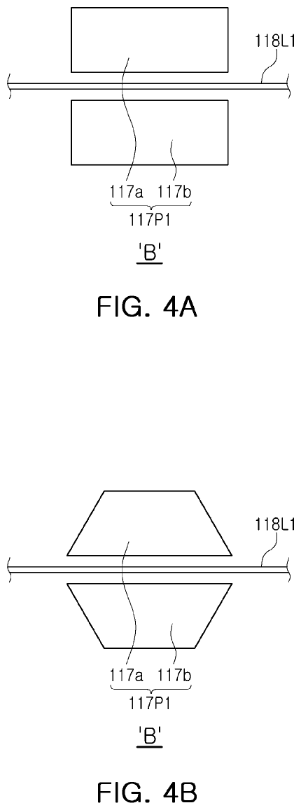

FIG. 3 is a partial plan view of a semiconductor package according to example embodiments. FIG. 3 is an enlarged view of a portion of a plane taken along line I-I′ of FIG. 2.

Referring to FIGS. 1 to 3, a semiconductor package 100 may include a package substrate 110, a semiconductor chip 120 on the package substrate 110, and upper bumps 130 connecting the semiconductor chip 120 to the package substrate 110, an encapsulant 150 for encapsulating the semiconductor chip 120, and connection bumps 160 on a lower surface of the package substrate 110.

The package substrate 110 is a support substrate on which the semiconductor chip 120 is mounted, and may be a substrate that enables connection pads 121 of the semiconductor chip 120 to be connected to connection bumps 160 that are arranged at an area larger than an area of the semiconductor chip 120. The substrate for a package may include or may be a printed circuit board (PCB), a ceramic substrate, a glass substrate, a tape wiring board, or the like. The package substrate 110 may include insulating layers 111, redistribution layers 112, redistribution vias 113, first and second solder mask layers 115 and 116 forming upper and lower surfaces, respectively, and ball pads 117 connected to the connection bumps 160, wiring lines 118, and lower vias 119. In embodiments, the number of insulating layers 111 and redistribution layers 112 constituting the package substrate 110 may be variously changed. In some embodiments, the package substrate 110 may be an interposer substrate, such as an organic interposer. In some embodiments, the package substrate 110 may be a module substrate, and in this case, the semiconductor chip 120 may be a semiconductor structure, such as a semiconductor package.

The insulating layers 111 may include or may be formed of an insulating material, for example, a thermosetting resin, such as epoxy resin, or a thermoplastic resin, such as polyimide. For example, the insulating layers 111 may include or may be formed of a photosensitive insulating material, such as a photo imageable dielectric (PID) resin. Alternatively, the insulating layers 111 may include or may be formed of a resin mixed with an inorganic filler, for example, Ajinomoto build-up film (ABF). Alternatively, the insulating layers 111 may include or may be formed of prepreg, flame retardant (FR-4), or bismaleimide triazine (BT). The insulating layers 111 may include the same or different materials. Boundaries between the insulating layers 111 may not be apparent according to materials constituting each layer and processes.

The redistribution layers 112 and the redistribution vias 113 may form an electrical path. The redistribution layers 112 and the redistribution vias 113 may redistribute a power, a ground or signals of the semiconductor chip 120 to a region outside the semiconductor chip 120, that is, a fan-out region that does not overlap the semiconductor chip 120 in a Z-direction. Accordingly, the semiconductor package 100 of the present embodiment may be referred to as a fan-out semiconductor package. However, a shape of the semiconductor package is not limited thereto, and in some embodiments, the semiconductor package 100 may form a fan-in semiconductor package.

The redistribution layers 112 and the redistribution vias 113 may include a ground pattern, a power pattern, and a signal pattern. For example, the redistribution layers 112 and the redistribution vias 113 may be connected with each other to form a path for supplying a ground voltage, a path for supplying a power voltage, or a path for supplying various signals such as control signals and data. The redistribution layers 112 may be arranged in a line shape on an X-Y plane, and the redistribution vias 113 may have a cylindrical shape having an inclined side surface so that a width thereof narrows upwardly or downwardly. The redistribution vias 113 are illustrated as a filled via structure in which an inside is completely filled with a conductive material, but is not limited thereto. For example, the redistribution vias 113 may have a conformal via shape in which a metal material is formed on an inner wall of the via hole.

The redistribution layers 112 and the redistribution vias 113 may include or may be formed of a conductive material, for example, copper (Cu), aluminum (Al), silver (Ag), tin (Sn), gold (Au), nickel (Ni), lead (Pb), titanium (Ti), or alloys thereof.

The redistribution layers 112 may include redistribution pads 112P exposed through the first solder mask layer 115. Some of the uppermost redistribution layers 112 may form redistribution pads 112P. The redistribution pads 112P may be pads for mounting the semiconductor chip 120. The redistribution pads 112P may be pads entirely exposed by the first solder mask layer 115 and may be connected to the upper bumps 130. In some embodiments, each of the redistribution pads 112P may further include a surface treatment layer disposed on a surface exposed from the first solder mask layer 115.

The first and second solder mask layers 115 and 116 may be solder resist layers protecting the redistribution layer 112 and the wiring lines 118 from external physical and chemical damage. The first and second solder mask layers 115 and 116 may include or may be formed of an insulating material, for example, prepreg, ABF, FR-4, BT, or photo solder resist (PSR). The first solder mask layer 115 may form an upper surface of the package substrate 110 and may have openings exposing at least a portion of the redistribution layer 112, for example, the redistribution pads 112P. The second solder mask layer 116 may have a plurality of openings exposing at least a portion of the redistribution layer 112, for example, the ball pads 117.

The ball pads 117, wiring lines 118, and lower vias 119 may be disposed on a lower surface LS of the package substrate 110. The lower surface LS of the package substrate 110 may refer to a lower surface of the entire insulating layers 111, except for the first and second solder mask layers 115 and 116, and an upper surface US may refer to an upper surface of the entire insulating layers 111. The ball pads 117, wiring lines 118, and lower vias 119 may electrically connect the redistribution layers 112 and the redistribution vias 113 to the connection bumps 160. The ball pads 117 may be directly connected to the connection bumps 160 through lower surfaces. The wiring lines 118 may include wiring patterns for routing. The wiring lines 118 may be located on the same level as that of the ball pads 117. The lower vias 119 on the lower surface LS may pass through the insulating layer 111 and extend to a lowermost redistribution layer among the upper redistribution layers 112. Lower surfaces of the lower vias 119 may be located on substantially the same level as that of lower surfaces of the ball pads 117.

As illustrated in FIG. 3, the ball pads 117 may have a shape corresponding to the connection bumps 160 in a plan view. For example, the ball pads 117 may have a circular shape and may be regularly arranged. However, the shape and arrangement of the ball pads 117 may be variously changed in embodiments. The ball pads 117 may include first and second ball pads 117P1 and 117P2 having different shapes.

The first ball pad 117P1 may include first and second pads 117a and 117b, which are two divided pads. The second ball pad 117P2 may include a third pad 117c as a single pad. Each of the first and second pads 117a and 117b may have a shape corresponding to a portion of one figure, for example, a portion of one circle or ellipse. For example, the first pad 117a may have a shape corresponding to an upper region of one circle, and the second pad 117b may have a shape corresponding to a lower region of the one circle. The first and second pads 117a and 117b may have a shape corresponding to a portion of the third pad 117c or a shape similar thereto. For example, the first pad 117a may have a shape corresponding to a first portion of the third pad 117c, and the second pad 117b may have a shape corresponding to a second portion of the third pad 117c. In some embodiments, the first and second portions of the third pad 117c may be different portions of the third pad 117c without overlapping each other. In some embodiments, the first and second portions of the third pad 117 may have the same area or different areas. The first and second pads 117a and 117b may have a shape corresponding to the third pad 117c as a whole. For example, the first and second pads 117a and 117b have a shape in which a portion of the third pad 117c is removed, and an outer circumferential surface thereof may have substantially the same shape as that of a portion of the third pad 117c.

A first wiring line 118L1 of the wiring lines 118 may extend between the first and second pads 117a and 117b. The first ball pad 117P1 may be disposed in at least partial regions, and a position in which the first ball pad 117P1 is disposed may be determined by considering a path of the wiring lines 118.

The first and second pads 117a and 117b may be substantially symmetrical based on the first wiring line 118L1. Each of the first and second pads 117a and 117b may have a maximum width W1 ranging from about 100 m to about 700 m. A width W2 of each of the first wiring lines 118L1 may be smaller than the maximum width W1 of the first and second pads 117a and 117b and may range from, for example, about 10 m to about 150 m. In some embodiments, the maximum width W1 may correspond to a width of a surface of each of the first and second pads 117a and 117b that extends along an extending direction of one of the first wiring lines 118L1 between the first and second pads 117a and 117b.

The wiring lines 118 may be disposed near the ball pads 117 and the lower vias 119 and may be connected to the ball pads 117 and the lower vias 119. The wiring lines 118 may include first and second wiring lines 118L1 and 118L2. The first wiring lines 118L1 may extend between the first and second pads 117a and 117b of the first ball pad 117P1. The second wiring lines 118L2 may extend along circumferences of the ball pads 117. Since the semiconductor package 100 may include the first ball pads 117P1 including the first and second pads 117a and 117b, the wiring lines 118 may extend through a space between the first and second pads 117a and 117b, thereby increasing a freedom of designing or routing the wiring lines 118 to minimize the number of the wiring lines 118 or to reduce lengths of the wiring lines 118.

As illustrated in FIG. 2, in the first ball pad 117P1 connected to one connection bump 160, the first and second pads 117a and 117b may be located on the same level as that of the first wiring line 118L1 therebetween. The first and second pads 117a and 117b may be symmetrically disposed on opposite sides of the first wiring line 118L1, and the connection bump 160 and the second solder mask layer 116 may also be disposed to have a symmetrical shape.

The first and second pads 117a and 117b may be disposed on a lower surface of the lowermost insulating layer 111. The lower surface of the lowermost insulating layer 111 may include a first portion that is covered with the second solder mask layer 116, and a second portion that is covered with the connection bump 160. Specifically, side surfaces of the first and second pads 117a and 117b facing the first wiring line 118L1 and portions of lower surfaces adjacent to the side surfaces may be exposed by first and second openings OP1 and OP2 of the second solder mask layer 116 to contact the connection bump 160. Side surfaces of the first and second pads 117a and 117b that do not face the first wiring line 118L 1, for example, outer surfaces and a portion of lower surfaces adjacent to the outer surfaces, may be covered with the second solder mask layer 116.

At least one of the first and second pads 117a and 117b may be connected to the redistribution via 113 through an upper surface thereof, but is not limited thereto. For example, as illustrated in FIG. 2, the second pad 117b may be connected to the redistribution via 113 and may be integral with the redistribution via 113. Opposite side surfaces and lower surfaces of the first wiring line 118L1 may be covered with the second solder mask layer 116.

The ball pads 117, wiring lines 118, and lower vias 119 may include a ground pattern, a power pattern, and a signal pattern. For example, in the first ball pad 117P1 illustrated in FIG. 2, the first wiring line 118L1 may be a ground pattern or a ground line, and the first and second pads 117a and 117b, and a redistribution layer 112a vertically overlapping the first wiring line 118L1 may be signal lines or signal patterns. In this case, since the first wiring line 118L1 is disposed between the first and second pads 117a and 117b, noise occurrence due to interference between upper and lower and/or left and right signal lines may be reduced.

The ball pads 117, the wiring lines 118, and the lower vias 119 may include or may be formed of a conductive material, for example, copper (Cu), aluminum (Al), silver (Ag), tin (Sn), gold (Au), nickel (Ni), lead (Pb), titanium (Ti), or alloys thereof.

The semiconductor chip 120 may be disposed on an upper surface of the package substrate 110 and may include connection pads 121 adjacent to the lower surface. The semiconductor chip 120 may be mounted on the package substrate 110 in a flip-chip bonding manner. The semiconductor chip 120 may include a device layer or an active layer located below the connection pads 121, and an integrated circuit (IC) is disposed in the device layer or the active layer. The semiconductor chip 120 may include a logic semiconductor chip and/or a memory semiconductor chip. The logic semiconductor chip may be a microprocessor, for example, a central processing unit (CPU), a graphic processing unit (GPU), a field programmable gate array (FPGA), an application processor (AP), a digital signal processor, a cryptographic processor, a controller, or an application specific integrated circuit (ASIC). The memory semiconductor chip may be a volatile memory, such as dynamic random access memory (DRAM) and static random access memory (SRAM), or a non-volatile memory, such as flash memory.

A body portion of the semiconductor chip 120 may include or may be formed of silicon (Si), germanium (Ge), gallium arsenide (GaAs), or the like, and the connection pads 121 may include or may be formed of a conductive material, such as tungsten (W), aluminum (Al), copper (Cu), and the like. The connection pads 121 may be pads of a bare chip, for example, aluminum (Al) pads, but may be pads of a packaged chip, for example, copper pads, according to embodiments.

The connection pads 121 may be electrically connected to the redistribution layer 112 through the upper bumps 130. In the present embodiment, the connection pads 121 are disposed in the body portion of the semiconductor chip 120 so that the lower surfaces thereof form the lower surface of the semiconductor chip 120, but the arrangement of the connection pads 121 is not limited thereto. In some embodiments, a passivation layer exposing the connection pads 121 may be further disposed on the lower surface of the semiconductor chip 120. The passivation layer may include or may be a silicon oxide layer and/or a silicon nitride layer.

The upper bumps 130 may physically and electrically connect the connection pads 121 of the semiconductor chip 120 to the redistribution pads 112P of the package substrate 110. The upper bumps 130 may have a ball or pillar shape, but are not limited thereto. The upper bumps 130 may include or may be formed of, for example, tin (Sn) or an alloy (Sn—Ag—Cu) including tin (Sn). In embodiments, the number of upper bumps 130 and the number and arrangement of redistribution pads 112P may be variously changed.

The encapsulant 150 may encapsulate and protect the semiconductor chip 120. The encapsulant 150 may be disposed to cover the side surfaces and the upper surface of the semiconductor chip 120, but is not limited thereto. The encapsulant 150 may include or may be formed of an insulating material, for example, a thermosetting resin, such as epoxy resin, a thermoplastic resin, such as polyimide, prepreg including inorganic filler and glass fiber, ABF, FR-4, BT, epoxy molding compound (EMC), or PID.

The connection bumps 160 may be disposed in openings of the second solder mask layer 116 on the lower surface LS of the package substrate 110. The connection bumps 160 may physically and/or electrically connect the semiconductor package 100 to an external device, such as a main board. The connection bumps 160 may have a size and diameter larger than the upper bumps 130. The connection bumps 160 may include or may be formed of, but are not limited to, a low melting point metal, such as tin (Sn) and an alloy (Sn—Ag—Cu) containing tin (Sn). The connection bumps 160 may have a land, ball, or pin shape, and may be formed of a single layer or multiple layers. For example, the connection bumps 160 may be solder balls.

As illustrated in FIG. 2, the connection bump 160 may contact a portion of a lower surface and a side surface of each of the first and second pads 117a and 117b in a region connected to the first ball pad 117P1. The connection bump 160 may contact side surfaces of the second solder mask layer 116 defining the first and second openings OP1 and OP2. Specifically, the connection bump 160 may contact, from the left side of FIG. 2, a portion of a lower surface and a side surface of the second solder mask layer 116, a portion of a lower surface and a first side surface of the first pad 117a, a portion of a lower surface of the insulating layer 111, side surfaces and a lower surface of the second solder mask layer 116 covering the first wiring line 118L1, a portion of the lower surface of the insulating layer 111, a first side surface and a portion of a lower surface of the second pad 117b, and a side surface and a portion of a lower surface of the second solder mask layer 116. The first side surfaces of the first and second pads 117a and 117b may be side surfaces facing the first wiring line 118L1. In the case of the second ball pad 117P2, the connection bump 160 may contact a lower surface of the third pad 117c and a portion of a lower surface and side surfaces of the second solder mask layer 116. Accordingly, the connection bump 160 may have a relatively large contact area with the first ball pad 117P1, and thus, stress may be reduced in a region connected to the first ball pad 117P, thereby preventing defects, such as occurrence of cracks.

An upper end of the connection bump 160 may be located on a level higher than that of lower surfaces of the first and second pads 117a and 117b, and may be located on substantially the same level as that of the upper surfaces of the first and second pads 117a and 117b. An uppermost surface of the connection bump 160 may be substantially coplanar with upper surfaces of the first and second pads 117a and 117b.

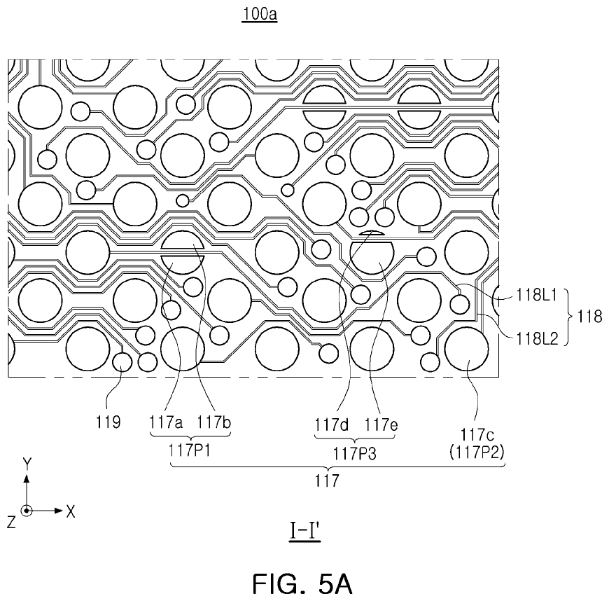

FIGS. 4A and 4B are partially enlarged views of a semiconductor package according to example embodiments. FIGS. 4A and 4B each illustrate a region corresponding to region ‘B’ of FIG. 3.

Referring to FIGS. 4A and 4B, the first ball pad 117P1 may have a quadrangular shape as illustrated in FIG. 4A or a hexagonal shape as illustrated in FIG. 4B. Accordingly, the first and second pads 117a and 117b may have a shape corresponding to a portion of a quadrangle or a portion of a hexagon.

As such, in the embodiments, the first ball pad 117P1 may have a various shape other than a circular shape. For example, a shape of the first ball pad 117P1 may have a polygonal shape as described with reference to FIGS. 4A and 4B or an elliptical shape.

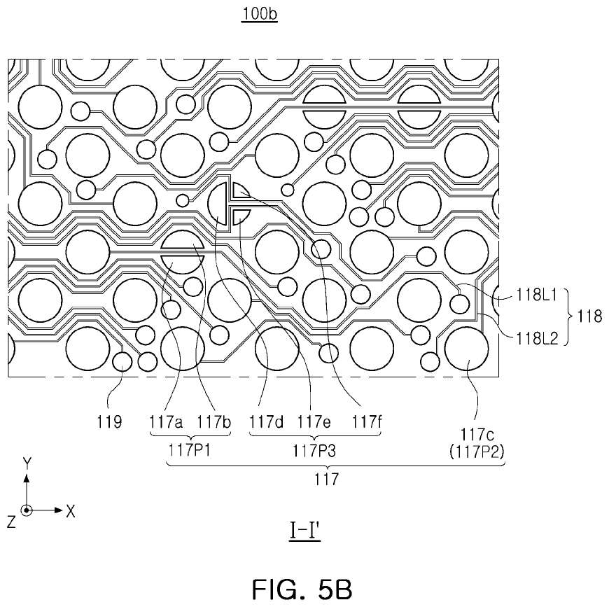

FIGS. 5A to 5C are plan views of a semiconductor package according to example embodiments. FIGS. 5A to 5C illustrate regions corresponding to FIG. 3.

Referring to FIG. 5A, in a semiconductor package 100a, the ball pads 117 may include first to third ball pads 117P1, 117P2, and 117P3 having different shapes. The description given above with reference to FIGS. 1 to 3 may be equally applied to the first and second ball pads 117P1 and 117P2.

The third ball pad 117P3 may include fourth and fifth pads 117d and 117e, which are two divided pads. Each of the fourth and fifth pads 117d and 117e may have a shape corresponding to a portion of one circle or one oval. The fourth and fifth pads 117d and 117e may have a shape corresponding to a portion of the third pad 117c or a shape similar thereto. The first wiring line 118L1 may extend between the fourth and fifth pads 117d and 117e. Unlike the first and second pads 117a and 117b, the fourth and fifth pads 117d and 117e may have an asymmetrical shape with respect to the first wiring line 118L1. The fourth and fifth pads 117d and 117e may have different sizes in a plan view based on the first wiring line 118L1. The fourth and fifth pads 117d and 117e may have a shape corresponding to the third pad 117c as a whole.

Referring to FIG. 5B, in a semiconductor package 100b, the ball pads 117 may include first to third ball pads 117P1, 117P2, and 117P3 having different shapes. The description given above with reference to FIGS. 1 to 3 may be equally applied to the first and second ball pads 117P1 and 117P2.

The third ball pad 117P3 may include fourth to sixth pads 117d, 117e, and 117f, which are three divided pads. Each of the fourth to sixth pads 117d, 117e, and 117f may have a shape corresponding to a portion of one circular shape or one oval shape. The fourth to sixth pads 117d, 117e, and 117f may have a shape corresponding to a portion of the third pad 117c or a shape similar thereto. The first wiring line 118L1 may extend between the fourth to sixth pads 117d, 117e, and 117f. The fourth to sixth pads 117d, 117e, and 117f may have a shape corresponding to the third pad 117c as a whole. In embodiments, the third ball pad 117P3 may include three or more pads, and the divided shape of the pads may be variously changed.

Referring to FIG. 5C, in a semiconductor package 100c, the ball pads 117 may include first to third ball pads 117P1, 117P2, and 117P3 having different shapes. The description given above with reference to FIGS. 1 to 3 may be equally applied to the first and second ball pads 117P1 and 117P2.

The third ball pad 117P3 may include one fourth pad 117d. The fourth pad 117d may have a shape corresponding to a portion of a circle or ellipse. The fourth pad 117d may have a shape corresponding to a portion of the third pad 117c or a shape similar thereto. The first wiring line 118L1 may extend to be adjacent to the fourth pad 117d.

For example, in the third ball pad 117P3 of the embodiment of FIG. 5A, if the size of the asymmetrically divided fifth pad 117e is relatively small, the fifth pad 117e may be omitted, thereby designing a form of the third ball pad 117P3 of the present embodiment. In embodiments, the shape and relative size of the fourth pad 117d may be variously changed.

In some embodiments, the ball pads 117 may include two or more of the third ball pads 117P3 of FIGS. 5A to 5C or may include all of the third ball pads 117P3 of the three embodiments.

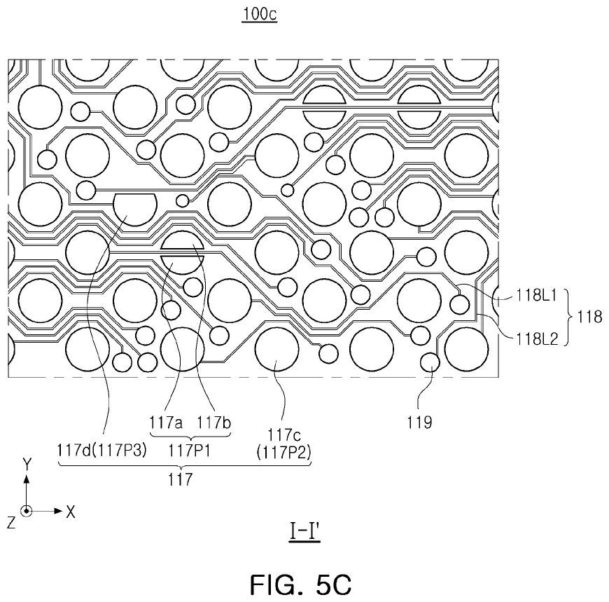

FIGS. 6A and 6B are partially enlarged views of a semiconductor package according to example embodiments. FIGS. 6A and 6B illustrate regions corresponding to FIG. 2.

Referring to FIG. 6A, in a semiconductor package 100d, the second solder mask layer 116d may cover an entire side surface of each of the first and second pads 117a and 117b and may cover a portion of each of the lower surfaces connected to the side surfaces. Alternatively, referring to FIG. 6B, in the semiconductor package 100e, the second solder mask layer 116e may cover the entire side surface of each of the first and second pads 117a and 117b and may cover a portion of the lower surface that is connected to an outer side surface among the side surfaces.

Accordingly, the connection bump 160 may contact a portion of the lower surface of each of the first and second pads 117a and 117b. The connection bumps 160 may contact, from the left side of FIGS. 6A and 6B, a portion of the lower surface and side surface of the second solder mask layers 116d and 116e, a portion of the lower surface of the first pad 117a, a surface of the second solder mask layers 116d and 116e covering the first wiring line 118L1, a portion of the lower surface of the second pad 117b, and the side surface and a portion of the lower surface of the second solder mask layers 116d and 116e.

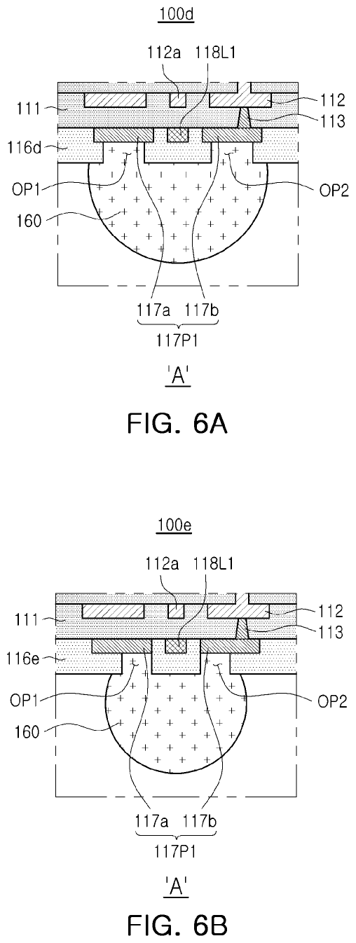

FIG. 7 is a cross-sectional view of a semiconductor package according to example embodiments.

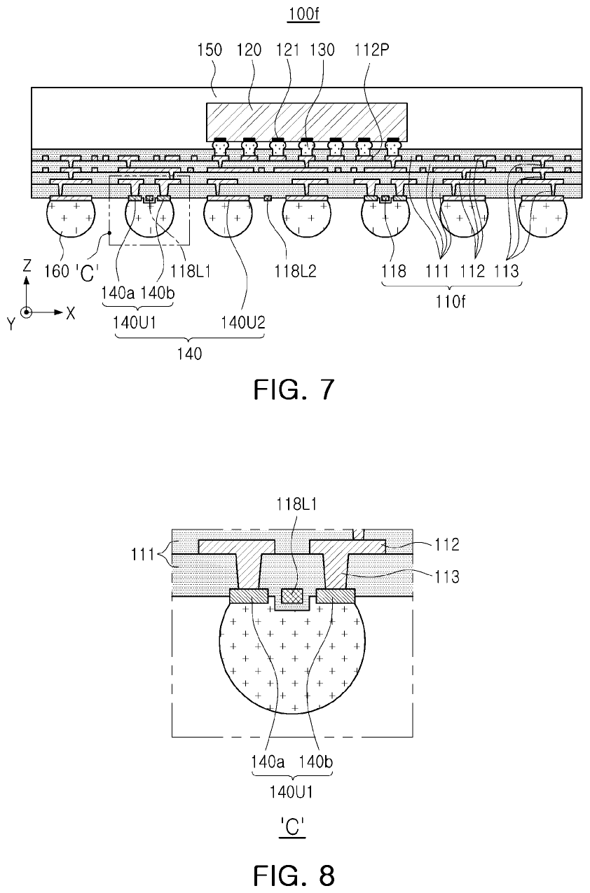

FIG. 8 is a partial enlarged view of a semiconductor package according to example embodiments. FIG. 8 is an enlarged view of region ‘C’ of FIG. 7.

Referring to FIGS. 7 and 8, a semiconductor package 100f may include a redistribution portion 110f, a semiconductor chip 120 on the redistribution portion 110f, upper bumps 130 connecting the semiconductor chip 120 to the redistribution portion 110f, an encapsulant 150 encapsulating the semiconductor chip 120, under bump metallization (UBM) layers 140 disposed below the redistribution portion 110f, and connection bumps 160 connected to the UBM layers 140.

The redistribution portion 110f may enable the connection pads 121 of the semiconductor chip 120 to be connected to the connection bumps 160 that include bumps disposed outside an outer boundary of the semiconductor chip 120, when viewed in a plan view. The redistribution portion 110f may include insulating layers 111, the redistribution layers 112 disposed on or within the insulating layers 111, redistribution vias 113 vertically connecting the redistribution layers 112 formed on different layers with each other, and first and second wiring lines 118L1 and 118L2. In the present embodiment, the insulating layers 111 may include or may be formed of a photosensitive insulating material, such as PID resin, and the redistribution layers 112 may be formed using a photolithography process. In embodiments, the number of insulating layers 111 and redistribution layers 112 constituting the redistribution portion 110f may be variously changed. In some embodiments, a lower end of the redistribution portion 110f may be located on the same level as that of a lower end of the UBM layer 140 and may further include lower vias 119 connected to the redistribution layers 112, similar to the embodiments of FIGS. 1 to 3.

The UBM layers 140 may be disposed on a lower surface of the redistribution portion 110f and may be partially buried in the insulating layer 111. However, in some embodiments, an upper surface of the UBM layer 140 may be located on the same level as that of a lower surface of the lowermost insulating layer 111. The UBM layers 140 may contact the connection bumps 160. The UBM layers 140 may have a shape corresponding to the connection bumps 160 in a plan view. For example, the UBM layers 140 may have a circular shape and may be regularly arranged.

The UBM layers 140 may include first and second UBM layers 140U1 and 140U2 having different shapes. The first UBM layer 140U1 may include first and second UBM pads 140a and 140b, which are two divided pads. The second UBM layer 140U2 may include one pad. The first and second UBM pads 140a and 140b may have a shape corresponding to a portion of a figure in a plan view. For example, the second UBM layer 140U2 may have a first shape such as a circular shape and an elliptical shape. The first UBM pad 140a may have a shape corresponding to a first portion of the first shape of the second UBM layer 140U2 in a plan view, and the second UBM pad 140b may have a shape corresponding to a second portion of the first shape of the second UBM layer 140U2 in a plan view. The first wiring line 118L1 may extend in a space between the first and second UBM pads 140a and 140b.

As illustrated in FIG. 8, the connection bumps 160 may contact a portion of a lower surface and a portion of a side surface of the first UBM pad 140a, a surface of the insulating layer 111 covering the first wiring line 118L 1, and a portion of a side surface and a portion of a lower surface of the second UBM pad 140b. In addition, the description of the first and second pads 117a and 117b given above with reference to FIGS. 1 to 3 may be equally applied to the first and second UBM pads 140a and 140b.

In the present embodiment, the first and second wiring lines 118L1 and 118L2 may be disposed on the same level as that of the UBM layers 140, and the first wiring lines 118L1, among the first and second wiring lines 118L1 and 118L2, may extend between the first and second UBM pads 140a and 140b, so that routing design connected to connection bumps 160 may be simplified.

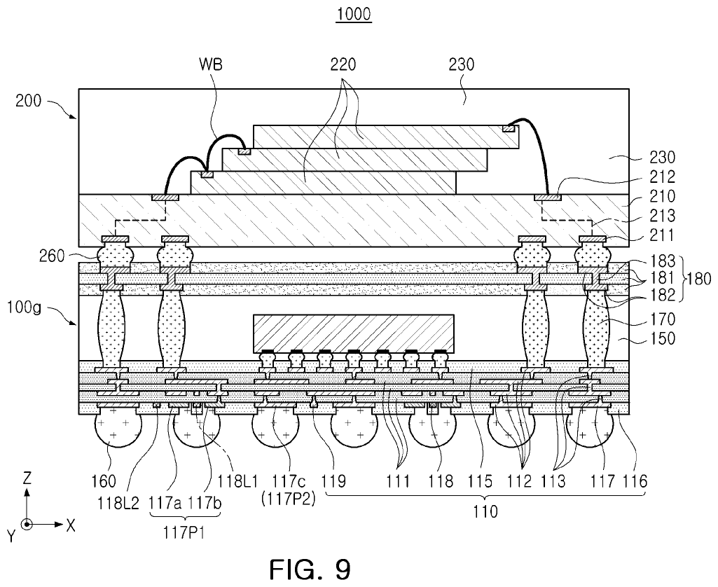

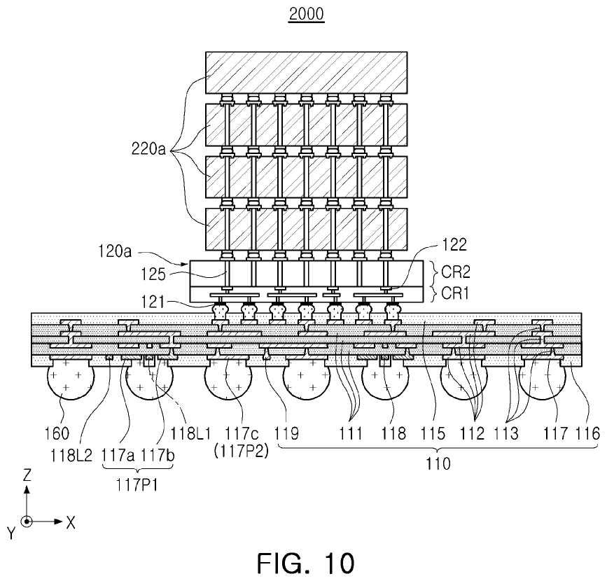

FIGS. 9 and 10 are cross-sectional views of a semiconductor package according to example embodiments.

Referring to FIG. 9, unlike the embodiment of FIG. 1, a semiconductor package 1000 may further include a second semiconductor package 200 disposed on a first semiconductor package 100g. That is, the semiconductor package 1000 may be a package-on-package (POP) type in which the second semiconductor package 200 is stacked on the first semiconductor package 100g, and may be functionally a system-in-package (SIP).

Compared to the semiconductor package 100 described above with reference to FIGS. 1 to 3, the first semiconductor package 100g may further include conductive posts 170 passing through the encapsulant 150 and an interposer substrate 180 on the conductive posts 170.

The conductive posts 170 may be disposed between the package substrate 110 and the interposer substrate 180 to electrically connect the package substrate 110 to the interposer substrate 180. The conductive posts 170 may extend between the package substrate 110 and the interposer substrate 180 in a vertical direction, for example, in the Z-direction, to provide a vertical connection path for electrically connect the redistribution layer 112 to the upper wiring layer 182. The conductive posts 170 may include or may be formed of, for example, tin (Sn), indium (In), bismuth (Bi), antimony (Sb), copper (Cu), silver (Ag), zinc (Zn), lead (Pb), or alloys thereof, and may have a spherical or ball shape extending in the Z-direction.

The interposer substrate 180 may be a substrate providing a redistribution layer on an upper surface of the first semiconductor package 100g, and may be disposed between the lower package and the upper package in the POP structure. The interposer substrate 180 may include upper insulating layers 181, upper wiring layers 182, and wiring vias 183. The upper insulating layers 181, the upper wiring layers 182, and the wiring vias 183 have characteristics that are the same as or similar to the insulating layers 111, the redistribution layers 112, and the redistribution vias 113 of the package substrate 110 described above, and thus, redundant descriptions are omitted. The uppermost and lowermost upper insulating layers 181, among the upper insulating layers 181, may be solder mask layers protecting the upper wiring layers 132 and include openings exposing at least a portion of the upper wiring layers 132.

The first semiconductor package 100g is illustrated as having a structure including the ball pads 117 according to the embodiments of FIGS. 1 to 3, but is not limited thereto. In example embodiments, any one of the semiconductor packages according to the embodiments described above with reference to FIGS. 1 to 8 may be employed as the first semiconductor package 100g.

In some embodiments, a structure of the first ball pad 117P1 may be applied to at least one of the redistribution layers 112 and the upper wiring layers 182 connected to the conductive posts 170, and thus, at least one of the redistribution layer 112 and the upper wiring layers 182 may have a divided shape. In this case, wiring lines may be further disposed between regions of the divided redistribution layers 112 and/or upper wiring layers 182.

The second semiconductor package 200 may include a substrate 210, upper semiconductor chips 220, an upper encapsulant 230, and upper connection bumps 260.

The substrate 210 may include upper pads 212 and lower pads 211 exposed through upper and lower surfaces thereof. The substrate 210 may include or may be formed of, for example, silicon (Si), glass, ceramic, or plastic. The substrate 210 may include an electrical path 213 based on wiring patterns therein, and the wiring patterns may have a multilayer structure.

The upper semiconductor chips 220 may include logic semiconductor chips and/or memory semiconductor chips. A device layer may be disposed on a lower portion of the upper semiconductor chips 220 so that a lower surface of the upper semiconductor chips 220 may be an active surface, but the arrangement position of the active surface may be variously changed in embodiments. The upper semiconductor chips 220 may be mounted on the substrate 210 by wire bonding or flip chip bonding. For example, the plurality of upper semiconductor chips 220 may be vertically stacked on the substrate 210 and electrically connected to the upper pad 212 of the substrate 210 by a bonding wire WB. For example, the upper semiconductor chips 220 may include a memory chip, and the semiconductor chip 120 of the first semiconductor package 100g may include an application processor (AP) chip.

The upper encapsulant 230 may be disposed to surround and cover the upper semiconductor chips 220 and serve to protect the upper semiconductor chips 220. The upper encapsulant 230 may be formed of, for example, a silicone-based material, a thermosetting material, a thermoplastic material, or a UV treated material.

The upper connection bumps 260 may be disposed on a lower surface of the substrate 210. The upper connection bumps 260 may connect the second semiconductor package 200 to the first semiconductor package 100g, so that the first and second semiconductor packages 100g and 200 may be electrically connected with each other. The upper connection bumps 260 may include at least one conductive material, for example, solder, tin (Sn), silver (Ag), copper (Cu), or aluminum (Al).

However, the structure of the second semiconductor package 200 is an example, and semiconductor packages having various structures may be stacked on the first semiconductor package 100g. In some embodiments, at least one of the lower pads 211 and the upper wiring layers 182 connected to the upper connection bumps 260 may have a divided shape like the first ball pad 117P1. In this case, wiring lines may be further disposed between regions of the divided redistribution layers 112 and/or upper wiring layers 182.

Referring to FIG. 10, unlike the embodiment of FIG. 1, a semiconductor package 2000 may further include a plurality of upper semiconductor chips 220a stacked on a semiconductor chip 120a on the package substrate 110. For example, the semiconductor package 2000 may be a SIP including a logic chip and memory semiconductor chips. The semiconductor chip 120a may be a logic semiconductor chip, and the upper semiconductor chips 220a may be memory semiconductor chips. Alternatively, the semiconductor chip 120a may be both a logic semiconductor chip and a memory semiconductor chip, and the upper semiconductor chips 220a may be memory semiconductor chips.

The semiconductor chip 120a of the present embodiment may have a lower first region CR1 and an upper second region CR2, and may further include device layers 122 and through-vias 125. The first region CR1 may be a device region, in which elements, such as transistors and memory cells constituting a semiconductor chip. The first region CR1 may be formed based on the second region CR2. The second region CR2 may be a substrate region, and may include or may be formed of, for example, a semiconductor material, such as silicon (Si). In FIG. 10, the semiconductor chip 120a is illustrated to be larger than the upper semiconductor chips 220a, but the size of the semiconductor chip 120a is not limited thereto. In some embodiments, the semiconductor chip 120a may have the same size as that of the upper semiconductor chips 220a.

The device layers 122 may be disposed in the first region CR1 to configure the devices. The through-vias 125 may pass through the second region CR2 of the semiconductor chip 120a. In some embodiments, the through-vias 125 may further pass through at least a portion of the first region CR1. The through-vias 125 may be electrically connected to the device layers 122 of the first region CR1 and may provide an electrical connection between the upper semiconductor chips 220a and the package substrate 110. The through-vias 125 may be formed of a conductive material, and may include or may be formed of, for example, at least one of tungsten (W), aluminum (Al), and copper (Cu).

In addition to the above description, the description of the semiconductor package 100 given above with reference to FIGS. 1 to 3 may be equally applied to the package substrate 110 and the semiconductor chip 120a.

The upper semiconductor chips 220a may be stacked on the semiconductor chip 120a in the Z-direction. The upper semiconductor chips 220a may include the through-vias 125 except for the upper semiconductor chip 220a at the top. Connection regions may be located between the semiconductor chip 120a and the upper semiconductor chip 220a and between the second semiconductor chips 220a. Although not specifically illustrated, at least a portion of the connection regions may have a structure that is the same as or similar to that of the connection region between the package substrate 110 and the semiconductor chip 120a.

The semiconductor package having improved design ease and reliability may be provided by a configuration of the connection structure of the ball pad, the wiring line, and the connection bump of the package substrate according to the present invention. Since the semiconductor package may include a divided ball pad configuration, a wiring line may extend through the divided ball pad configuration, thereby increasing a freedom of designing or routing wiring lines to minimize a number of the wiring lines or to reduce lengths of the wiring lines.

While example embodiments have been illustrated and described above, it will be apparent to those skilled in the art that modifications, variations, and combinations could be made without departing from the scope of the present inventive concept as defined by the appended claims.

What is claimed is:

1. A semiconductor package comprising:
a package substrate including:
a ball pad including first and second pads on a lower surface of the package substrate,
a wiring line extending between the first pad and the second pad on the lower surface, and
a solder mask layer covering the wiring line and the ball pad,
wherein the solder mask layer includes a first opening exposing a portion of the first pad and a second opening exposing a portion of the second pad;
a semiconductor chip on an upper surface of the package substrate; and
a connection bump on a lower surface of the ball pad and connected to the first and second pads,
wherein the connection bump covers a lower surface and a first side surface of the first pad exposed through the first opening, a lower surface and side surfaces of a region of the solder mask layer covering the wiring line, and a lower surface and a first side surface of the second pad exposed through the second opening.

2. The semiconductor package of claim 1,
wherein the connection bump covers side surfaces of the solder mask layer defining the first and second openings.

3. The semiconductor package of claim 1,
wherein the first side surfaces of the first and second pads are side surfaces facing the wiring line.

4. The semiconductor package of claim 1, wherein
wherein the package substrate further includes insulating layers and redistribution layers that are vertically and alternately stacked on each other,
wherein the connection bump contacts a first portion and a second portion of a lowermost insulating layer, among the insulating layers, and
wherein the first portion of the lowermost insulating layer is exposed between the wiring line and the first side surface of the first pad, and the second portion of the lowermost insulating layer is exposed between the wiring line and the first side surface of the second pad.

5. The semiconductor package of claim 1,
wherein the wiring line is a ground line, and at least one of the first and second pads are electrically connected to a first signal line.

6. The semiconductor package of claim 5,
wherein the package substrate further includes insulating layers and redistribution layers that are alternately and vertically stacked on each other,
wherein the redistribution layers include a first redistribution layer that is adjacent to and perpendicularly overlaps the wiring line, and
wherein the first redistribution layer is configured to form a second signal line.

7. The semiconductor package of claim 1,
wherein the package substrate further includes:
insulating layers and redistribution layers that are alternately and vertically stacked on each other, and
redistribution vias connected to the redistribution layers, and
wherein at least one of the first and second pads is connected to at least one of the redistribution vias.

8. The semiconductor package of claim 1,
wherein at least one of the first and second pads has a maximum width having a value selected from a range of about 100 m to about 700 m.

9. The semiconductor package of claim 1,
wherein the wiring line has a width having a value selected from a range from about 10 m to about 150 m.

10. The semiconductor package of claim 1,
wherein the first and second pads are symmetrically disposed on opposite sides of the wiring line, and
wherein the connection bump has a symmetrical shape with respect to the wiring line.

11. The semiconductor package of claim 1,
wherein the first and second pads have an asymmetrical shape with respect to the wiring line.

12. The semiconductor package of claim 1,
wherein the first pad has a shape corresponding to a first portion of a circle,
wherein the second pad has a shape corresponding to a second portion of the circle,
wherein the ball pad further includes a third pad having a shape corresponding to a third portion of the circle, and
wherein the wiring line extends between the first and third pads or between the second and third pads.

13. The semiconductor package of claim 1,
wherein the package substrate further includes a lower via arranged to be connected to the wiring line on the lower surface of the package substrate.

14. A semiconductor package comprising:
a package substrate including:
a first ball pad including a first pad and a second pad that are disposed on a lower surface of the package substrate,
a second ball pad including a third pad having a first shape and disposed on the lower surface of the package substrate,
a wiring line extending between the first pad and the second pad on the lower surface, and
a solder mask layer covering the wiring line and the first ball pad, wherein the solder mask layer includes a first opening exposing a portion of the first pad and a second opening exposing a portion of the second pad; and
a connection bump on a lower surface of the first ball pad and connected to the first and second pads,
wherein the first pad has a shape corresponding to a first portion of the first shape of the third pad in a plan view,
wherein the second pad has a shape corresponding to a second portion of the first shape of the third pad in a plan view, and
wherein the connection bump contacts a portion of a lower surface and a side surface of each of the first and second pads.

15. The semiconductor package of claim 14,
wherein an upper end of the connection bump is located at a level higher than a level of the lower surface of each of the first and second pads.

16. The semiconductor package of claim 14,
wherein an uppermost surface of the connection bump is substantially coplanar with upper surfaces of the first and second pads.

17. The semiconductor package of claim 14,
wherein the second ball pad is spaced apart from the first ball pad, and
wherein the first shape of the second ball pad is a circle.

18. The semiconductor package of claim 14,
wherein the package substrate further includes a third ball pad spaced apart from each of the first ball pad and the second ball pad, and
wherein the third ball pad includes a fourth pad having a shape corresponding to a portion of the first shape of the third pad of the second ball pad.

19. A semiconductor package comprising:
a package substrate including:
a first ball pad on a lower surface of the package substrate,
a second ball pad on the lower surface of the package substrate, and
a solder mask layer exposing portions of each of the first and second ball pads;
a semiconductor chip on an upper surface of the package substrate;
a first connection bump on a lower surface of the first ball pad and connected to the first ball pad; and
a second connection bump on a lower surface of the second ball pad and connected to the second ball pad,
wherein the first ball pad includes first and second pads each having a shape corresponding to a portion of a first figure,
wherein the second ball pad includes third and fourth pads each having a shape corresponding to a portion of a second figure,
wherein the package substrate further includes:
a first wiring line extending between the first pad and the second pad on the lower surface of the package substrate; and
a second wiring line between the third pad and the fourth pad on the lower surface of the package substrate, and
wherein the first ball pad has a shape different from a shape of the second ball pad.

20. The semiconductor package of claim 19,
wherein the first connection bump contacts at least a portion of a side surface of each of the first and second pads and a lower surface of each of the first and second pads, and
wherein the second connection bump contacts at least a portion of a side surface of each of the third and fourth pads and a lower surface of each of the third and fourth pads.
